(19) United States
(12) Patent Application Publication
(10) Pub. No.: US 2011/0098939 A1
(43) Pub. Date: Apr. 28, 2011

(54) PROCESS ANALYTIC SENSOR WITH LOW POWER MEMORY WRITE FUNCTION

(75) Inventors: Behzad Rezvani, Anaheim, CA (US); Jeffrey Lomibao, Corona, CA (US); Calin Ciobanu, Brea, CA (US)

(73) Assignee: Rosemount Analytical Inc., Irvine, CA (US)

(21) Appl. No.: 12/911,994

(22) Filed: Oct. 26, 2010

Related U.S. Application Data
(60) Provisional application No. 61/255,183, filed on Oct. 27, 2009.

(51) Int. Cl. G06F 19/00; G01N 31/00; G11C 7/10

(52) U.S. Cl. 702/30; 365/189.16

(57) ABSTRACT

A process analytic sensor is provided. The process analytic sensor includes a process analytic sensing element that is coupleable to a process. The process analytic sensing element has an electrical characteristic that varies with an analytical aspect of the process. A microcontroller is disposed within the process analytic sensor and is coupled to the process analytic sensing element to sense the electrical characteristic and provide an analytical signal based on the sensed characteristic. The microcontroller is operable on as little as 0.5 milliamps and includes electrically erasable programmable read only memory (EEPROM) that can be written while the microcontroller operates on as little as 0.5 milliamps.

### CROSS-REFERENCE TO RELATED APPLICATION

The present application is based on and claims the benefit of U.S. provisional patent application Ser. No. 61/255,183, filed Oct. 27, 2009, the content of which is hereby incorporated by reference in its entirety.

### BACKGROUND

Process analytic sensors are generally configured to couple to a given process, such as an oil refining process or a pharmaceutical manufacturing process, and provide an analytical output relative to the process. Examples of such analytical outputs include, but not limited to: measurement of pH; measurement of oxidation reduction potential; selective ion measurement; and measurement of dissolved gases such as dissolved oxygen. These analytical measurements can then be provided to a control system such that process control can be effected and/or adjusted based upon the analytic measurement. Such sensors are generally continuously, or substantially continuously, exposed to the process medium.

The environments within which process analytic sensors operate are sometimes volatile or even explosive. In order to ensure that sensors and associated electronic equipment do not generate sources of ignition within such volatile environments, energy storage and/or discharge rates are generally limited. Intrinsic safety requirements set forth specifications which ensure that compliant electrical devices will not generate sources of ignition within volatile or explosive process environments. Intrinsic safety requirements are intended to guarantee that instrument operation or failure cannot cause ignition if the instrument is properly installed in an environment that contains explosive gases. This is accomplished by limiting the maximum energy stored in the process analytic device in a worst case failure situation. Excessive energy discharge may lead to sparking or excessive heat which could ignite an explosive environment in which the process analytic device is operating.

Examples of intrinsic safety requirements include European, CENELEC Standards, EN500014 and 50020, Factory Mutual Standard, FM3610, the Canadian Standard Association, the British Approval Service for Electrical Equipment Inflammable Atmospheres, the Japanese Industrial Standard, and the Standards Association of Australia.

In order to ensure stringent compliance with automation industry safety protocols and specifications, only equipment certified by an independent agency can be used in such locations. Since process analytic sensors and equipment is often used in such volatile environments, it is highly desirable for such devices to be designed to meet intrinsic safety requirements, or at least provide an option of intrinsic safety compliance.

Process analytic sensors are currently undergoing a significant shift in technology. Previously, an analog process analytic sensor, such as a pH sensor, would be mated to an analyzer and then a series of calibration steps would be performed to essentially calibrate the sensor/analyzer assembly. If the pH sensor were then moved to a different analyzer, the entire process would need to be repeated. While such process analytic sensors were of the analog nature, some did include analog preamplifier circuitry in order to provide a robust signal to the analyzer. The recent innovation stems from the utilization of digital electronics within the sensor itself. These new “smart” process analytic sensors are able to communicate digitally with the analyzer. However, in order to facilitate industry acceptance of such sensors, the sensors themselves should still be able to operate on power budgets and signaling levels of previous analog-based sensors. This creates a difficult tension between intrinsic safety requirements, industry-accepted power budgets, and the array of new features provided by digital circuitry within the sensor itself. Achieving a useful balance between these various design considerations would provide a smart process analytic sensor that would meet with industry approval more readily.

### SUMMARY

A process analytic sensor is provided. The process analytic sensor includes a process analytic sensing element that is coupleable to a process. The process analytic sensing element has an electrical characteristic that varies with an analytical aspect of the process. A microcontroller is disposed within the process analytic sensor and is coupled to the process analytic sensing element to sense the electrical characteristic and provide an analytical signal based on the sensed characteristic. The microcontroller is operable on as little as 0.5 milliamps and includes electrically erasable programmable read only memory (EEPROM) that can be written while the microcontroller operates on as little as 0.5 milliamps.

### BRIEF DESCRIPTION OF THE DRAWINGS

FIG. 1 is a diagrammatic view of a process analyzer coupled to a process analytic sensor in accordance with an embodiment of the present invention.

FIG. 2 is a system block diagram of a process analyzer coupled to a process analytic sensor in accordance with an embodiment of the present invention.

FIG. 3 is a system block diagram of an exemplary microcontroller coupled to a power storage/charging circuit in accordance with an embodiment of the present invention.

FIG. 4 is a flow diagram of a method of writing data to memory of a process analytic sensor in accordance with an embodiment of the present invention.

### DETAILED DESCRIPTION OF ILLUSTRATIVE EMBODIMENTS

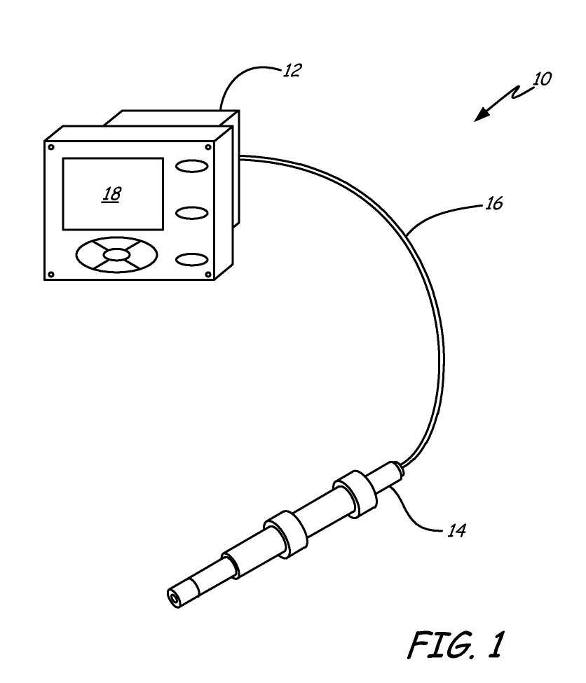

FIG. 1 is a diagrammatic view of a process analytic system with which embodiments of the present invention are particularly useful. System 10 includes a process analyzer 12 coupled to a process analytic sensor 14 via cable 16. In the embodiment illustrated in FIG. 1, process analytic sensor 14 is an insertion-type process analytic pH sensor. However, embodiments of the present invention can be practiced with any process analytic sensor. Process analytic sensor 14 is configured to be inserted within a process, or otherwise coupled to a process, such that sensor 14 senses an analytic characteristic, such as pH and provides an electrical indication thereof. The electrical indication is received by analyzer 12 which then applies suitable signal conditioning and/or calculations to determine a process analytic output. The process analytic output may then be indicated on display 18 or conveyed to some other suitable device or entity. In some embodiments, sensor analyzer 12 may be coupled to a known 4-20 mA current loop and receive all of its operating power from the loop. In such situations, the amount of current that can be used to power sensor 14 is severely limited. For example, sensor 14 should be operable on as little as 0.5 mA. Moreover, in such installations, the low power requirement is sometimes part of an overall requirement for intrinsic safety. Thus, in such embodiments the total capacitance within sensor 14 is also limited. For example, the total capacitance within sensor 14 should be at or less than about 0.255 μF. While these design limitations had significantly less impact on analog-based process analytic sensors of the past, they seriously constrain the ability to operate digital circuitry within process analytic sensor 14. If the digital circuitry were to consume too much power (for example, beyond 0.5 milliamps) errors or other deleterious effects could ensue.

The provision of digital circuitry within a process analytic sensor provides a number of advantages. For example, process analytic sensor calibration information that would typically be required to be generated each time a sensor is paired with an analyzer can simply be loaded into the process analytic sensor by the manufacturer. Accordingly, then the process analytic sensor can simply upload or otherwise transmit its calibration information to any analyzer to which it is coupled. In this manner, significant calibration setup time is reduced. Further still, should a user wish to perform an additional calibration when the process analytic sensor is coupled to a first analyzer, that calibration information can be stored or otherwise saved within the process analytic sensor itself such that the information can be transmitted or provided to a second analyzer if the sensor is later coupled to the second analyzer. Further still, user and/or application-specific data for the sensor can be saved within the sensor itself thereby facilitating user setup. Finally, the provision of digital electronics within sensor 14 allows sensor 14 to perform diagnostic operations and potentially communicate diagnostic information back to the analyzer. Thus, the potential need for recalibration and/or maintenance can be determined by the process analytic sensor itself and such information can be communicated to the analyzer as an alert or other suitable indication. Accordingly, the provision of digital electronics, and specifically a microcontroller, within process analytic sensor 14 provides myriad new features and advantageous over traditional analog-base process analytic sensors.

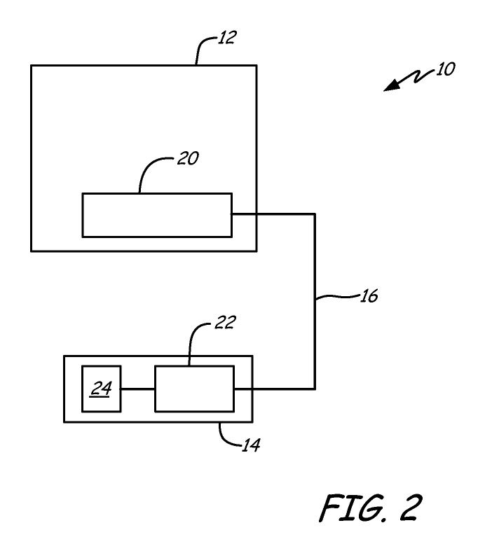

FIG. 2 is a system block diagram of process analytic system 10 illustrated in FIG. 1. Analyzer 12 includes a smart signal card or module 20 that is coupled to cable 16. Module 20 typically includes a dedicated microcontroller to handle digital communication over cable 16 with microcontroller 22 of sensor 14. In one embodiment, microcontroller 20 is sold by Atmel Corporation of San Jose, Calif., under the trade designation ATmega88. The communication through cable 16 is preferably in accordance with known communication techniques among and between microcontrollers.

Process analytic sensor 14 includes process analytic sensor microcontroller 22 coupled to microcontroller 20 via cable 16. Microcontroller 20 is preferably a low-power CMOS 8-bit microcontroller based on the AVR enhanced RISC architecture. Microcontroller 22 is configured to operate on an extremely low power budget. For example, microcontroller 22 operates on as little as 0.5 milliamps and includes circuitry that helps achieve compliance with intrinsic safety requirements. For example, the total capacitance of all capacitors within process analytic sensor 14, in the illustrated embodiment, sum to no more than 0.255 μF. In one embodiment, micro controller 22 is sold by Atmel Corporation under the trade designation ATtiny84. One design challenge for process analytic sensor 14 is the operation as a two-wire instrument with the significant power constrains (0.5 milliamps). One particular operation of microcontroller 22 that is challenging is the writing of data to the electronic erasable programmable read only memory (EEPROM) within microcontroller 22. While reading data can be accomplished within a 0.5 milliamp reading process, the writing of data to the EEPROM requires a current that is approximately 20 times higher than that available from the 0.5 milliamp supply. This happens due to the fact that EEPROM uses higher energy in the writing of the data process. If there is an attempt to write data to the EEPROM without power limitation considerations, this can create significant problems for process analytic sensor 14 ranging from potential reset of the sensor 14 to an entire shutdown or failure of sensor 14.

In accordance with an embodiment of the present invention, writing to EEPROM within microcontroller 22 is done within a 0.5 milliamp current budget. The data to be written to EEPROM is divided into small packets, such as single bytes, and the energy necessary to write each packet is stored in local capacitance within microcontroller 22. The writing pauses after each packet long enough to recharge the local capacitance for the next packet. Packets are placed in mapped EEPROM the same way as if the writing would be done in continuous mode.

Microcontroller 22 is coupled to process analytic sensor element 24 which has an electrical characteristic that varies with the process analytic variable of interest. In the embodiment illustrated in FIG. 2, element 24 is a pH electrode that has an electrical characteristic that varies with the pH of the process media within which process analytic sensor 14 is immersed. This electrical characteristic is transduced or otherwise determined by microcontroller 22 and conveyed through cable 16 to microcontroller 20 of analyzer 12.

Sensors, such as process analytic sensor 14, that include digital circuitry help eliminate the need for field calibration since the as-tested calibration data is embedded in the sensor's memory. Analyzer 12 then reads this calibration information automatically, providing immediate live process measurements. This saves significant resources and is believed to provide significant advantages to end users. The capability to read the embedded calibration information can be provided in various analyzers. One process analytic sensor that includes such digital circuitry is sold by Emerson Process Management under the trade designation PERpH-X® pH sensor.

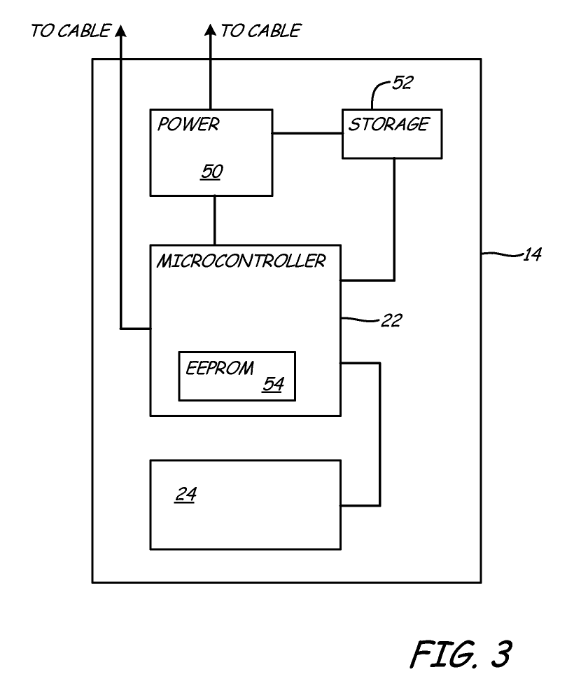

FIG. 3 is a system block diagram of an exemplary microcontroller coupled to a power storage/charging circuit in accordance with an embodiment of the present invention. Microcontroller 22 is coupled to power module 50 that includes suitable current limiting circuitry to ensure that process analytic sensor 14 does not consume too much power. In one embodiment, module 50 ensures that no more than 0.5 milliamps is drawn by process analytic sensor 14. Module 50 is coupled to power storage device 52, which is preferably a capacitor. In some intrinsic safety embodiments, the value of power storage capacitor may be selected to be the difference between 0.255 μF and the sum of all the capacitances of all other capacitors within process analytic sensor 14. Regardless, power storage device 52 has sufficient capacity to store enough energy to allow microcontroller 22 to write at least one byte of information to EEPROM 54. During a write operation, microcontroller 22 will consume significantly more current than is available to process analytic sensor 14 via cable 16. This additional current is provided by power storage device 52, which stores excess current when microcontroller 22 is not drawing more than 0.5 milliamps. Microcontroller 22 is coupled to power storage device 52 and is able to determine when sufficient energy is stored for a write operation. In one embodiment, microcontroller 22 may include an analog-to-digital converter that is able to measure the voltage across power storage device 52.

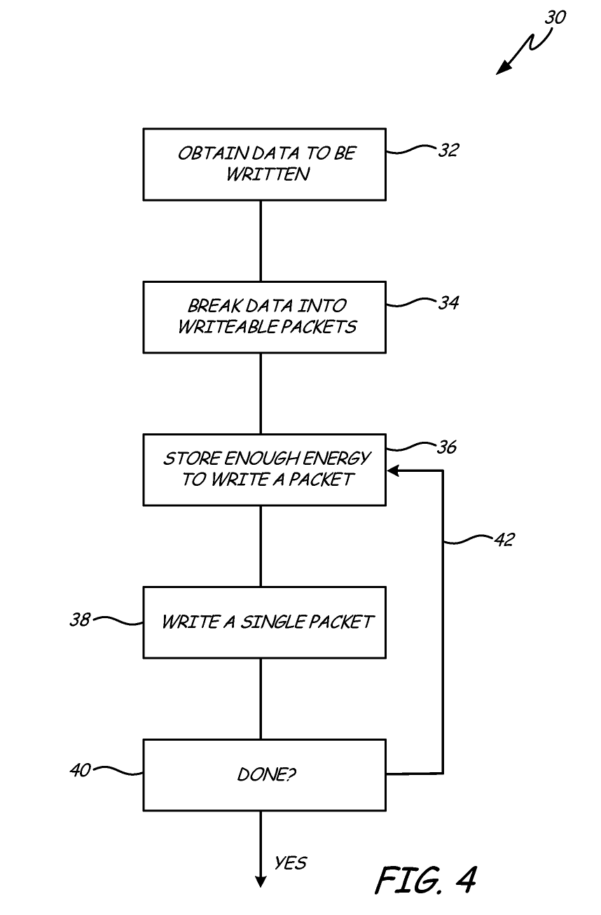

FIG. 4 is flow diagram of a method of writing data to EEPROM memory within a microcontroller of a process analytic sensor in accordance with an embodiment of the present invention. Method 30 begins at block 32 where data to be written to EEPROM memory is obtained. This data can be calibration data, user-specific data, application-data, or any suitable data that the user would like to be embedded within process analytic sensor 14. Next, at block 34, the data is broken into writeable packets. A writeable packet is a packet that is small enough to be written entirely with energy stored in local capacitance within microcontroller 22. Accordingly, the size of a writeable packet will vary depending on the size of the capacitance. In intrinsically-safe embodiments, the overall capacitance of all capacitors within process analytic sensor 14 and specifically within microcontroller 22 does not exceed 0.25 μF. Thus, while the write operation would otherwise consume more than 20 times the current available to the process analytic sensor, the energy for the write operation can be stored in the local capacitance and when the energy is sufficient to write a writeable packet, the local capacitance can be discharged and that discharge energy can be used for the write operation. In a preferred embodiment, a writable packet is a single byte of data. At block 36, one or more capacitors within process analytic sensor 14, are charged with sufficient energy to write a single writeable packet. Once sufficient energy is stored, method 30 progresses to block 38 where the single packet is written. The determination of whether sufficient energy is stored can be accomplished by measuring the voltage across the one or more capacitors and comparing the measured voltage with a selected threshold. Alternatively, the charge process can be performed for a selected period of time, since a minimum current draw (0.5 milliamps) can be assumed and multiplied by a known charge rate. Next, at block 40, the method determines whether all writeable packets have been written. If so, the method ends. However, if additional packets remain, control returns to block 36 along line 42 where additional energy is stored in order to write the next packet. The method loops until all writable packets had been written to the EEPROM.

Although the present invention has been described with reference to preferred embodiments, workers skilled in the art will recognize that changes may be made in form and detail without departing from the spirit and scope of the invention.

What is claimed is:

1. A process analytic sensor comprising:
a process analytic sensing element coupleable to a process and having an electrical characteristic that varies with an analytical aspect of the process;
a microcontroller disposed within the process analytic sensor, the microcontroller being coupled to the process analytic sensing element to sense the electrical characteristic and provide an analytical signal based on the sensed characteristic; and
wherein the microcontroller is operable on as little as 0.5 milliamps and includes electrically erasable programmable read only memory (EEPROM) that can be written while the microcontroller operates on as little as 0.5 milliamps.

2. The process analytic sensor of claim 1, wherein the EEPROM stores calibration data.

3. The process analytic sensor of claim 1, wherein the process analytic sensing element is a pH sensing element.

4. The process analytic sensor of claim 1, wherein the microcontroller is a CMOS microcontroller.

5. The process analytic sensor of claim 4, wherein the CMOS microcontroller is an 8-bit microcontroller.

6. The process analytic sensor of claim 1, wherein the process analytic sensor is intrinsically safe.

7. A method for writing electrically erasable programmable read only memory (EEPROM) in a process analytic sensor, the method comprising:
obtaining a quantity of data to be written to the EEPROM;
breaking the quantity of data into writeable packets;
charging at least one local capacitor to a preselected level;
writing a single writeable packet to the EEPROM; and
iterating the steps of charging the at least one local capacitor and writing a single packet until all writeable packets have been written to the EEPROM.

8. The method of claim 7, wherein the quantity of data is calibration data for the process analytic sensor.

9. The method of claim 8, wherein the calibration data is pH sensor calibration data.

10. The method of claim 7, wherein the EEPROM is embodied within a microcontroller of the process analytic sensor.

11. The method of claim 7, wherein the at least one local capacitor has a capacitance that is less than about 0.255 μF.

12. The method of claim 7, wherein the size of each writeable packet is a function of capacitance of the at least one local capacitor.

13. The method of claim 7, wherein a writeable packet size is a single byte of data.
